(19) United States
(12) Patent Application Publication
(10) Pub. No.: US 2013/0025532 A1
(43) Pub. Date: Jan. 31, 2013

(54) FORMATION OF PHOTOVOLTAIC ABSORBER LAYERS ON FOIL SUBSTRATES

(71) Applicant: NANOSOLAR, INC., San Jose, CA (US)

(72) Inventors: Craig Leidholm, Sunnyvale, CA (US); Brent Bollman, Belmont, CA (US)

(73) Assignee: NANOSOLAR, INC., San Jose, CA (US)

(21) Appl. No.: 13/645,443

(22) Filed: Oct. 4, 2012

Related U.S. Application Data
(63) Continuation of application No. 11/747,001, filed on May 10, 2007, now abandoned.
Application No. 11/747,001 is a continuation-in-part of application No. 10/943,685, filed on Sep. 18, 2004, now abandoned.
Application No. 10/943,685 is a continuation-in-part of application No. 11/740,915, filed on Apr. 26, 2007.

(51) Int. Cl. H01L 31/18

(52) U.S. Cl. 118/50; 118/58

(57) ABSTRACT

An absorber layer of a photovoltaic device may be formed on an aluminum or metallized polymer foil substrate. A nascent absorber layer containing one or more elements of group IB and one or more elements of group IIIA is formed on the substrate. The nascent absorber layer and/or substrate is then rapidly heated from an ambient temperature to an average plateau temperature range of between about 200° C. and about 600° C. and maintained in the average plateau temperature range 1 to 30 minutes after which the temperature is reduced.

### CROSS-REFERENCE TO RELATED APPLICATION

This application is a continuation of U.S. patent application Ser. No. 11/747,001 filed May 10, 2007, which is a continuation-in-part of U.S. patent application Ser. No. 10/943,685 filed Sep. 18, 2004 and a continuation-in-part of U.S. patent application Ser. No. 11/740,915 filed Apr. 26 2007, the entire disclosures of which are fully incorporated herein by reference for all purposes.

### FIELD OF THE INVENTION

The present invention relates to fabrication of photovoltaic devices and more specifically to processing and annealing of absorber layers for photovoltaic devices.

### BACKGROUND OF THE INVENTION

Efficient photovoltaic devices, such as solar cells, have been fabricated using absorber layers made with alloys containing elements of group IB, IIIA and VIA, e.g., alloys of copper with indium and/or gallium or aluminum and selenium and/or sulfur. Such absorber layers are often referred to as CIGS layers and the resulting devices are often referred to as CIGS solar cells. The CIGS absorber layer may be deposited on a substrate. It would be desirable to fabricate such an absorber layer on an aluminum foil substrate because Aluminum foil is relatively inexpensive, lightweight, and flexible. Unfortunately, current techniques for depositing CIGS absorber layers are incompatible with the use of aluminum foil as a substrate.

Typical deposition techniques include evaporation, sputtering, chemical vapor deposition, and the like. These deposition processes are typically carried out at high temperatures and for extended times. Both factors can result in damage to the substrate upon which deposition is occurring. Such damage can arise directly from changes in the substrate material upon exposure to heat, and/or from undesirable chemical reactions driven by the heat of the deposition process. Thus very robust substrate materials are typically required for fabrication of CIGS solar cells. These limitations have excluded the use of aluminum and aluminum-foil based foils.

An alternative deposition approach is the solution-based printing of the CIGS precursor materials onto a substrate. Examples of solution-based printing techniques are described, e.g., in Published PCT Application WO 2002/084708 and commonly-assigned U.S. patent application Ser. No. 10/782,017, both of which are incorporated herein by reference. Advantages to this deposition approach include both the relatively lower deposition temperature and the rapidity of the deposition process. Both advantages serve to minimize the potential for heat-induced damage of the substrate on which the deposit is being formed.

Although solution deposition is a relatively low temperature step in fabrication of CIGS solar cells, it is not the only step. In addition to the deposition, a key step in the fabrication of CIGS solar cells is the selenization and annealing of the CIGS absorber layer. Selenization introduces selenium into the bulk CIG or CI absorber layer, where the element incorporates into the film, while the annealing provides the absorber layer with the proper crystalline structure. In the prior art, selenization and annealing has been performed by heating the substrate in the presence of H₂Se or Se vapor and keeping this nascent absorber layer at high temperatures for long periods of time.

While use of aluminum (Al) as a substrate for solar cell devices would be desirable due to both the low cost and lightweight nature of such a substrate, conventional techniques that effectively anneal the CIGS absorber layer also heat the substrate to high temperatures, resulting in damage to Al substrates. There are several factors that result in Al substrate degradation upon extended exposure to heat and/or selenium-containing compounds for extended times. First, upon extended heating, the discrete layers within a Mo-coated Al substrate can fuse and form an intermetallic back contact for the device, which decreases the intended electronic functionality of the Mo-layer. Second, the interfacial morphology of the Mo layer is altered during heating, which can negatively affect subsequent CIGS grain growth through changes in the nucleation patterns that arise on the Mo layer surface. Third, upon extended heating, Al can migrate into the CIGS absorber layer, disrupting the function of the semiconductor. Fourth, the impurities that are typically present in the Al foil (e.g. Si, Fe, Mn, Ti, Zn, and V) can travel along with mobile Al that diffuses into the solar cell upon extended heating, which can disrupt both the electronic and optoelectronic function of the cell. Fifth, when Se is exposed to Al for relatively long times and at relatively high temperatures, aluminum selenide can form, which is unstable. In moist air the aluminum selenide can react with water vapor to form aluminum oxide and hydrogen selenide. Hydrogen selenide is a highly toxic gas, whose free formation can pose a safety hazard. For all these reasons, high-temperature deposition, annealing, and selenization are therefore impractical for substrates made of aluminum or aluminum alloys.

Because of the high-temperature, long-duration deposition and annealing steps, CIGS solar cells cannot be effectively fabricated on aluminum substrates (e.g. flexible foils comprised of Al and/or Al-based alloys) and instead must be fabricated on heavier substrates made of more robust (and more expensive) materials, such as stainless steel, titanium, or molybdenum foils, glass substrates, or metal- or metal-oxide coated glass. Thus, even though CIGS solar cells based on aluminum foils would be more lightweight, flexible, and inexpensive than stainless steel, titanium, or molybdenum foils, glass substrates, or metal- or metal-oxide coated glass substrates, current practice does not permit aluminum foil to be used as a substrate.

Thus, there is a need in the art, for a method for fabricating CIGS solar cells on aluminum substrates.

### BRIEF DESCRIPTION OF THE DRAWINGS

The teachings of the present invention can be readily understood by considering the following detailed description in conjunction with the accompanying drawings, in which:

FIG. 1 is a cross-sectional schematic diagram illustrating fabrication of an absorber layer according to an embodiment of the present invention.

FIG. 2 is a view of a heating assembly according to an embodiment of the present invention.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the exemplary embodiments of the invention described below are set forth without any loss of generality to, and without imposing limitations upon, the claimed invention.

Embodiments of the present invention allow fabrication of CIGS absorber layers on aluminum foil substrates. The invention lends itself to several variants (which remain, however, optional) used as alternatives or in combination. According to embodiments of the present invention, a nascent absorber layer containing elements of group IB and IIIA formed on an aluminum substrate by solution deposition may be annealed by rapid heating from an ambient temperature to a plateau temperature range of between about 200° C. and about 600° C. The temperature is maintained in the plateau range for between about 2 minutes and about 15 minutes, and subsequently reduced. Alternatively, the annealing temperature could be modulated to oscillate within a temperature range without being maintained at a particular plateau temperature.

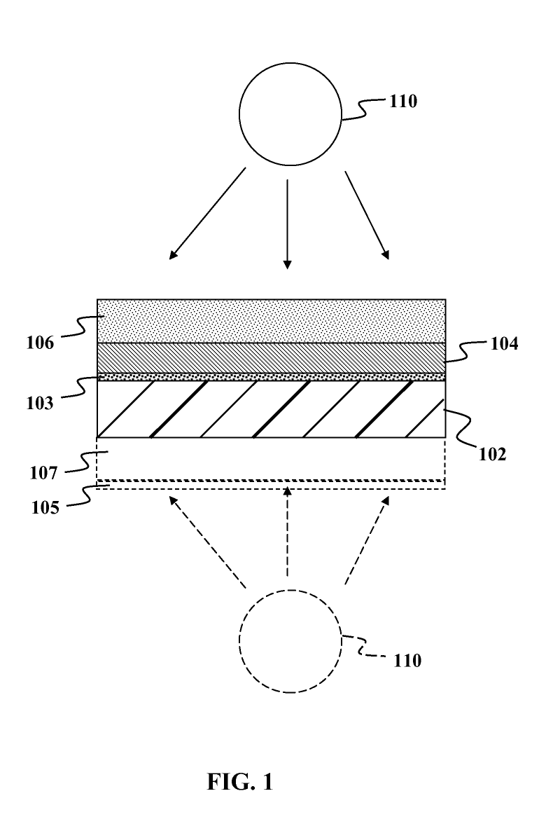

FIG. 1 depicts a partially fabricated photovoltaic device 100, and a rapid heating unit 110 the device generally includes an aluminum foil substrate 102, an optional base electrode 104, and a nascent absorber layer 106. The aluminum foil substrate 102 may be approximately 5 microns to one hundred or more microns thick and of any suitable width and length. The aluminum foil substrate 102 may be made of aluminum or an aluminum-based alloy. Alternatively, the aluminum foil substrate 102 may be made by metallizing a polymer foil substrate, where the polymer is selected from the group of polyesters, polyethylene naphtalates, polyetherimides, polyethersulfones, polyetheretherketones, polyimides, and/or combinations of the above. By way of example, the substrate 102 may be in the form of a long sheet of aluminum foil suitable for processing in a roll-to-roll system. The base electrode 104 is made of an electrically conducive material compatible with processing of the nascent absorber layer 106. By way of example, the base electrode 104 may be a layer of molybdenum, e.g., about 0.1 to 5 microns thick, and optionally from about 0.1 to 1.0 microns thick. The base electrode layer may be deposited by sputtering or evaporation or, alternatively, by chemical vapor deposition (CVD), atomic layer deposition (ALD), sol-gel coating, electroplating and the like.

Aluminum and molybdenum can and often do inter-diffuse into one another, with deleterious electronic and/or optoelectronic effects on the device 100. To inhibit such inter-diffusion, an intermediate, interfacial layer 103 may be incorporated between the aluminum foil substrate 102 and molybdenum base electrode 104. The interfacial layer may be composed of any of a variety of materials, including but not limited to chromium, vanadium, tungsten, and glass, or compounds such as nitrides (including but not limited to titanium nitride, tantalum nitride, tungsten nitride, hafnium nitride, niobium nitride, zirconium nitride vanadium nitride, silicon nitride, or molybdenum nitride), oxynitrides (including but not limited to oxynitrides of Ti, Ta, V, W, Si, Zr, Nb, Hf, or Mo), oxides, and/or carbides. The material may be selected to be an electrically conductive material. In one embodiment, the materials selected from the aforementioned may be those that are electrically conductive diffusion barriers. The thickness of this layer can range from 10 nm to 50 nm or from 10 nm to 30 nm. Optionally, the thickness may be in the range of about 50 nm to about 1000 nm. Optionally, the thickness may be in the range of about 100 nm to about 750 nm. Optionally, the thickness may be in the range of about 100 nm to about 500 nm. Optionally, the thickness may be in the range of about 110 nm to about 300 nm. In one embodiment, the thickness of the layer 103 is at least 100 nm or more. In another embodiment, the thickness of the layer 103 is at least 150 nm or more. In one embodiment, the thickness of the layer 103 is at least 200 nm or more. Optionally, some embodiments may include another layer such as but not limited to an aluminum layer above the layer 103 and below the base electrode layer 104. This layer may be thicker than the layer 103. Optionally, it may be the same thickness or thinner than the layer 103. This layer 103 may be placed on one or optionally both sides of the aluminum foil (shown as layer 105 in phantom in FIG. 1).

If barrier layers are on both sides of the aluminum foil, it should be understood that the protective layers may be of the same material or they may optionally be different materials from the aforementioned materials. The bottom protective layer 105 may be any of the materials. Optionally, some embodiments may include another layer 107 such as but not limited to an aluminum layer above the layer 105 and below the aluminum foil 102. This layer 107 may be thicker than the layer 103 (or the layer 104). Optionally, it may be the same thickness or thinner than the layer 103 (or the layer 104). Although not limited to the following, this layer 107 may be comprised of one or more of the following: Mo, Cu, Ag, Al, Ta, Ni, Cr, NiCr, or steel. Some embodiments may optionally have more than one layer between the protective layer 105 and the aluminum foil 102. Optionally, the material for the layer 105 may be an electrically insulating material such as but not limited to an oxide, alumina, or similar materials. For any of the embodiments herein, the layer 105 may be used with or without the layer 107.

The nascent absorber layer 106 may include material containing elements of groups IB, IIIA, and (optionally) VIA. Optionally, the absorber layer copper (Cu) is the group IB element, Gallium (Ga) and/or Indium (In) and/or Aluminum may be the group IIIA elements and Selenium (Se) and/or Sulfur (S) as group VIA elements. The group VIA element may be incorporated into the nascent absorber layer 106 when it is initially solution deposited or during subsequent processing to form a final absorber layer from the nascent absorber layer 106. The nascent absorber layer 106 may be about 1000 nm thick when deposited. Subsequent rapid thermal processing and incorporation of group VIA elements may change the morphology of the resulting absorber layer such that it increases in thickness (e.g., to about twice as much as the nascent layer thickness under some circumstances).

Fabrication of the absorber layer on the aluminum foil substrate 102 is relatively straightforward. First, the nascent absorber layer is deposited on the substrate 102 either directly on the aluminum or on an uppermost layer such as the electrode 104. By way of example, and without loss of generality, the nascent absorber layer may be deposited in the form of a film of a solution-based precursor material containing nanoparticles that include one or more elements of groups IB, IIIA and (optionally) VIA. Examples of such films of such solution-based printing techniques are described e.g., in commonly-assigned U.S. patent application Ser. No. 10/782,017, entitled “SOLUTION-BASED FABRICATION OF PHOTOVOLTAIC CELL” and also in PCT Publication WO 02/084708, entitled “METHOD OF FORMING SEMICONDUCTOR COMPOUND FILM FOR FABRICATION OF ELECTRONIC DEVICE AND FILM PRODUCED BY SAME” the disclosures of both of which are incorporated herein by reference.

Alternatively, the nascent absorber layer 106 may be formed by a sequence of atomic layer deposition reactions or any other conventional process normally used for forming such layers. Atomic layer deposition of IB-IIIA-VIA absorber layers is described, e.g., in commonly-assigned, co-pending application Ser. No. 10/943,658 entitled “FORMATION OF CIGS ABSORBER LAYER MATERIALS USING ATOMIC LAYER DEPOSITION AND HIGH THROUGHPUT SURFACE TREATMENT ON COILED FLEXIBLE SUBSTRATES”, (Attorney Docket No. NSL-035), which has been incorporated herein by reference above. It should be understood that the foil may be up to about 2 meters wide in length in some embodiments.

The nascent absorber layer 106 is then annealed by flash heating it and/or the substrate 102 from an ambient temperature to an average plateau temperature range of between about 200° C. and about 600° C. with the heating unit 110. Optionally, the temperature may be greater than 400° C. Optionally, the temperature may be greater than 500° C. The heating unit 110 optionally provides sufficient heat to rapidly raise the temperature of the nascent absorber layer 106 and/or substrate 102 (or a significant portion thereof) e.g., at between about 5 C.°/sec and about 150 C.°/sec. By way of example, the heating unit 110 may include one or more infrared (IR) lamps that provide sufficient radiant heat. By way of example, 8 IR lamps rated at about 500 watts each situated about ⅛″ to about 1″ from the surface of the substrate 102 (4 above and 4 below the substrate, all aimed towards the substrate) can provide sufficient radiant heat to process a substrate area of about 25 cm² per hour in a 4″ tube furnace. The lamps may be ramped up in a controlled fashion, e.g., at an average ramp rate of about 10 C.°/sec. Those of skill in the art will be able to devise other types and configurations of heat sources that may be used as the heating unit 110. For example, in a roll-to-roll manufacturing line, heating and other processing can be carried out by use of IR lamps spaced 1″ apart along the length of the processing region, with IR lamps equally positioned both above and below the substrate, and where both the IR lamps above and below the substrate are aimed towards the substrate. Alternatively, IR lamps could be placed either only above or only below the substrate 102, and/or in configurations that augment lateral heating from the side of the chamber to the side of the substrate 102. It should be understood, of course, that other heating sources may be used to provide the desired heating ramp rate.

The absorber layer 106 and/or substrate 102 are maintained in the average plateau temperature range for between about 1 minute and about 15 minutes, between about 1 and about 30 minutes. Optionally, the total time including the ramp may be in the range of about 1 to about 5 minutes, about 1 to about 10 minutes, about 1 minute to about 15 minutes, between about 1 and about 30 minutes. For example, the temperature may be maintained in the desired range by reducing the amount of heat from the heating unit 110 to a suitable level. In the example of IR lamps, the heat may be reduced by simply turning off the lamps. Alternatively, the lamps may be actively cooled. The temperature of the absorber layer 106 and/or substrate 102 is subsequently reduced to a suitable level, e.g., by further reducing or shutting off the supply of heat from the heating unit 110. Optionally, the total heating time may be in the range of about 1 minute and about 15 minutes, between about 1 and about 30 minutes.

In some embodiments of the invention, group VIA elements such as selenium or sulfur may be incorporated into the absorber layer either before or during the annealing stage. Alternatively, two or more discrete or continuous annealing stages can be sequentially carried out, in which group VIA elements such as selenium or sulfur are incorporated in a second or latter stage. The first annealing stage may be in a non-reactive atmosphere and the second or later stage may be in a reactive atmosphere. For example, the nascent absorber layer 106 may be exposed to H₂Se gas, H₂S gas, S, and/or Se vapor before or during flash heating or rapid thermal processing (RTP). Any of the foregoing may be used with a carrier gas such as but not limited to an inert gas, to assist with transport. In this embodiment, the relative brevity of exposure allows the aluminum substrate to better withstand the presence of these gases and vapors, especially at high heat levels.

Once the nascent absorber layer 106 has been annealed additional layers may be formed to complete the device 100. For example a window layer is typically used as a junction partner for the absorber layer. By way of example, the junction partner layer may include cadmium sulfide (CdS), indium sulfide (In2S3), zinc sulfide (ZnS), or zinc selenide (ZnSe) or some combination of two or more of these. Layers of these materials may be deposited, e.g., by chemical bath deposition, chemical surface deposition, or spray pyrolysis, to a thickness of about 50 nm to about 100 nm. In addition, a transparent electrode, e.g., a conductive oxide layer, may be formed on the window layer by sputtering, vapor deposition, CVD, ALD, electrochemical atomic layer epitaxy and the like.

Embodiments of the present invention overcome the disadvantages associated with the prior art by rapid thermal processing of nascent CIGS absorber layers deposited or otherwise formed on aluminum substrates. Aluminum substrates are much cheaper and more lightweight than conventional substrates. Thus, solar cells based on aluminum substrates can have a lower cost per watt for electricity generated and a far shorter energy payback period when compared to conventional silicon-based solar cells. Furthermore aluminum substrates allow for a flexible form factor that permits both high-throughput roll-to-roll printing during solar cell fabrication and faster and easier installation processes during solar module and system installation.

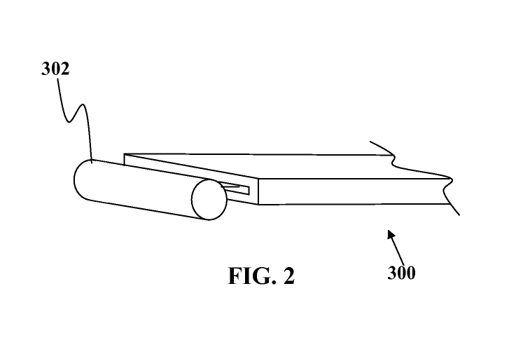

Referring now to FIG. 2, a chamber 300 for RTP selenization or sulfurization is provided. Optionally this chamber may also be used for heating in non-reactive gases. Although not limited to the following, the chamber may accommodate foils from about 4 inches to about 2 meters in width. The chamber may be designed with openings sized to handle foils of such widths. In one embodiment, the openings are sized so as to provide minimal clearance above and below the foil to reduce the amount of gas escaping. In one embodiment, the amount of space above and below are less than about 3 inches. In one embodiment, the amount of space above and below are less than about 2 inches. In one embodiment, the amount of space above and below are less than about 1 inch. In one embodiment, the amount of space above and below are less than about 0.5 inches. Although not limited to the following, the ratio of the interior width to the interior height at the narrow points in the chamber may be at least 10:1. Although not limited to the following, the ratio of the interior width to the interior height at the narrow points in the chamber may be greater than 10:1. Optionally, in one embodiment of a roll-to-roll format, an RTP furnace can be affected created by using a tunnel made of thermally conductive material (graphite, metal, etc. . . . ). At the roll to roll web section enters the tunnel, it experiences a ramp rate similar to an RTP system. This change in temperature delta can optionally be increased if the roller 302 comprises of a chilled roller and is positioned just at the entrance of the tunnel to cool the web just prior to entering the tunnel, us minimizing any effect of the web conducting heat back to the section outside the tunnel A chilled roller on either side is optional and can similarly be positioned at the exit of the tunnel to effect a fast ramp down rate.

Embodiments of the present invention allow the fabrication of lightweight and inexpensive photovoltaic devices on aluminum substrates. Flash heating/rapid thermal processing of the nascent absorber layer 106 allows for proper annealing and incorporation of group VIA elements without damaging or destroying the aluminum foil substrate 102. The plateau temperature range is sufficiently below the melting point of aluminum (about 660° C.) to avoid damaging or destroying the aluminum foil substrate. The use of aluminum foil substrates can greatly reduce the materials cost of photovoltaic devices, e.g., solar cells, made on such substrates thereby reducing the cost per watt. Economies of scale may be achieved by processing the aluminum foil substrate in a roll-to-roll fashion, with the various layers of the photovoltaic devices being built up on the substrate as it passes through a series of deposition annealing and other processing stages.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. The following related applications are fully incorporated herein by reference for all purposes: U.S. patent application Ser. Nos. 10/782,017, 10/810,072, 10/829,109, 10/829,662, 10/829,928, 10/943,657, 10/836,307, 10/943,657, 10/966,338, 10/943,659, 10/943,685, 11/039,053, and 11/243,492.

Embodiments of the present invention allow the fabrication of lightweight and inexpensive photovoltaic devices on aluminum substrates. Flash heating/rapid thermal processing of the nascent absorber layer 106 allows for proper annealing and incorporation of group VIA elements without damaging or destroying the aluminum foil substrate 102. The plateau temperature range is sufficiently below the melting point of aluminum (about 660° C.) to avoid damaging or destroying the aluminum foil substrate. The use of aluminum foil substrates can greatly reduce the materials cost of photovoltaic devices, e.g., solar cells, made on such substrates thereby reducing the cost per watt. Economies of scale may be achieved by processing the aluminum foil substrate in a roll-to-roll fashion, with the various layers of the photovoltaic devices being built up on the substrate as it passes through a series of deposition annealing and other processing stages.

While the above is a complete description of the preferred embodiment of the present invention, it is possible to use various alternatives, modifications and equivalents. For example, those of skill in the art will recognize that any of the embodiments of the present invention can be applied to almost any type of solar cell material and/or architecture. Although the present invention primarily discusses CIGS absorber layer, the foil substrate may be used with absorber layers that include silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)2, Cu(In,Ga,Al)(S,Se,Te)2, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C60 molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

For any of the embodiments herein, the layer may include a continuous layer or optionally a discontinuous layer having, in particular, patterns (either by etching of a continuous layer or by direct deposition of the discontinuous layer with the desired pattern, or by a mask system for example). This applies to any of the layers involved in the present application.

Therefore, the scope of the present invention should be determined not with reference to the above description but should, instead, be determined with reference to the appended claims, along with their full scope of equivalents. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. An apparatus for manufacturing a photovoltaic device comprising a substrate transport system for continuously providing a substrate to: a zone capable of providing an environment for deposition of a conductive back layer; a non-vacuum zone capable of providing an environment for deposition of a semiconductor absorber layer, wherein this zone comprises two discrete annealing stages, one stage in a non-reactive gas and a second stage in a group VIA gas; a zone capable of providing an environment for depositing a junction partner semiconductor layer; and a zone capable of providing an environment for deposition of a transparent conductive front layer.

2. The apparatus for manufacturing a photovoltaic device of claim 1 further comprising a means for providing in sequence a substrate to a plurality of reactor zones for preparing said substrate.

3. The apparatus for manufacturing a photovoltaic device of claim 1 further comprising a first processing zone capable of providing an environment for transition of the substrate from an ambient environment to the processing environment.

4. The apparatus of claim 3 wherein the substrate transitions, in part or whole, from atmospheric pressure to reduced pressure consistent with the subsequent processing environment.

5. The apparatus for manufacturing a photovoltaic device of claim 1 further comprising a processing zone capable of providing an environment for deposition of a barrier layer.

6. The apparatus of claim 5 wherein the barrier layer comprises a thin conductor or very thin insulating material.

7. The apparatus for manufacturing a photovoltaic device of claim 1 further comprising a processing zone capable of providing an environment for deposition of a conductive back contact layer.

8. The apparatus of claim 7 wherein the deposition of a conductive back contact layer comprises a metallic layer.

9. The apparatus of claim 8 wherein the metallic layer comprises conductive metals chosen from the group consisting of molybdenum, titanium, tantalum, and other acceptable metals or alloys.

10. The apparatus of claim 9 wherein the metallic layer is molybdenum.

11. The apparatus for manufacturing a photovoltaic device of claim 1 further comprising a processing zone capable of providing an environment for deposition of alkali materials.

12. The apparatus of claim 11 wherein the alkali materials are Na-VII or Na₂-VII.

13. The apparatus for manufacturing a photovoltaic device of claim 1 further comprising a processing zone capable of providing an environment for deposition of a semiconductor layer.

14. The apparatus of claim 13 wherein the semiconductor layer comprises Group I, III, VI elements.

15. The apparatus of claim 14 wherein the semiconductor layer comprises CuGaSe₂, CuAlSe₂, or CuInSe₂ alloyed with one or more of the I, III, VI elements.

16. The apparatus of claim 15 wherein the semiconductor layer comprises CuGaSe₂.

17. The apparatus of claim 1 wherein the reactive gas comprises at least one of H₂Se, H₂S, and/or Se.

18. An apparatus for manufacturing a photovoltaic device comprising a substrate transport system for providing in sequence a substrate to a plurality of reactor zones comprising: a processing zone capable of providing an environment for transition of the substrate from an ambient environment to the processing environment, wherein the substrate transitions, in part or whole, from atmospheric pressure to reduced pressure consistent with the subsequent processing environment; a processing zone capable of providing an environment for deposition of a conductive back layer, wherein the deposition of a conductive back contact layer comprises a metallic layer comprised of molybdenum; a processing zone capable of providing an environment for deposition of a barrier layer wherein the barrier layer comprises a thin conductor or very thin insulating material; a non-vacuum processing zone capable of providing an environment for deposition of a semiconductor layer wherein the semiconductor layer comprises CuGaSe₂, CuAlSe₂, or CuInSe₂ alloyed with one or more of the I, III, VI elements, wherein this zone comprises two discrete annealing stages, one stage in a non-reactive gas and a second stage in a group VIA gas; a processing zone capable of providing an environment for deposition of alkali materials, wherein the alkali materials are Na-VII or Na₂-VII; a processing zone capable of providing an environment for deposition of a another semiconductor layer wherein the semiconductor layer comprises a I-(IIIa,IIIb)-VI₂ layer; a processing zone capable of providing an environment for thermal treatment of one or more layers thus forming a p-type absorber layer wherein the treatment occurs in the pressure range of 10⁻⁶ torr up to atmospheric pressure and temperature range of 300.degree. C. to 700.degree. C.; a processing zone capable of providing an environment for deposition an n-type semiconductor layer wherein the n-type semiconductor layer comprises one or more of the following group (In,Ga)_{y}(Se,S,O) or the following group (Zn,Cd) (Se,S,O); a processing zone capable of providing an environment for deposition of a transparent conductive front layer wherein the insulating transparent semiconductor layer comprises one or more materials ZnO or ITO; and a processing zone capable of providing an environment for deposition of a conducting transparent semiconductor layer, wherein the conducting transparent semiconductor layer comprises one or more materials ZnO, Cd₂SnO₄ or ITO.
